(19) United States
(12) Patent Application Publication
(10) Pub. No.: US 2026/0322404 A1
(43) Pub. Date: Oct. 15, 2026

(54) DESIGNING BASIS MATRICES FOR QUASI-CYCLIC LDPC CODES

(71) Applicant: Orange, Issy-Les-Moulineaux (FR)

(72) Inventor: Bruno JAHAN, Chatillon Cedex (FR)

(21) Appl. No.: 19/479,242

(22) PCT Filed: Apr. 24, 2024
(86) PCT No.: PCT/EP2024/061163

§ 371 Date: Oct. 27, 2025

(30) Foreign Application Priority Data
Apr. 28, 2023 (FR) FR2304316

(51) Int. Cl. H03M 13/11; H03M 13/00

(52) U.S. Cl. CPC H03M 13/1168; H03M 13/616

(57) ABSTRACT

A method for coding at least one block of K.Z source data, delivering at least one codeword of size N.Z, with Z an integer expansion factor, Z≥1, the method implementing coding of the K.Z source data using a parity matrix H of size (M.Z×N.Z). The parity matrix H is obtained from a base matrix BG′ of size M×N, by replacing each element of the base matrix BG′ with an expansion matrix of size Z×Z, the base matrix BG′ being expressed in the form:

$${BG}^{′} = [ \begin{matrix}A & B & 0 \\ C & D & I\end{matrix} ] .$$

The extension matrix C includes at least two consecutive blocks of rows, each including a different number of rows, equal to a prime number or to the square of a prime number, each block of rows including at least one occurrence of a diagonal matrix.

### CROSS-REFERENCE TO RELATED APPLICATIONS

This application is filed under 35 U.S.C. § 371 as the U.S. National Phase of Application No. PCT/EP2024/061163 entitled “DESIGNING BASIS MATRICES FOR QUASI-CYCLIC LDPC CODES” and filed Apr. 24, 2024, and which claims priority to FR2304316 filed Apr. 28, 2023, each of which is incorporated by reference in its entirety.

### BACKGROUND

### Field

The field of the invention is that of digital communications.

More specifically, the invention relates to error correcting codes, in particular but not exclusively to LDPC (low density parity check) error correcting codes.

The invention is applicable in particular in the field of data storage or transmission, for example via wireless communications (for example using radio waves or unguided optical waves) or wired communications (for example using optical fibers or electric cables).

The invention is applicable in particular in all fields in which it is sought to offer good transmission reliability, for example for radio transmissions (Wi-Fi®, 5G, 6G, etc.).

### Description of the Related Technology

FIG. 1 illustrates a transmitter in a digital transmission chain. Such a transmitter uses conventional signal processing modules.

The source data 11, for example binary data coming from a source that generates video data (for example a source of animated images, of virtual-reality or augmented-reality images, a source of an image sequence), audio data (for example voice), flow control data, be these of video or audio or another type, or coming from a sensor, an actuator, etc., are thus coded in a channel coding block 12 so as to introduce redundancy. The coded data are then interleaved in an interleaving block 13 so as to mix the coded data. A mapping block 14 makes it possible to convert the coded data into constellation points (BPSK, QPSK, 16QAM, etc.). The associated symbols are framed 15 and modulated in a single-carrier or multicarrier modulation block 16, for example of OFDM (orthogonal frequency-division multiplexing) type.

In order to improve the robustness of communications via a communication channel, it is known to use error correcting codes in the channel coding block 12. For example, LDPC codes, turbo-codes, polar codes, or else Reed-Salomon codes offer good performance in terms of error correction.

Turbo-codes have been selected in particular for the 4G mobile telephony standard, and LDPC codes have been selected for the 5G mobile telephony standard.

The main features of LDPC codes, as defined in the 5G standard in particular, will be recalled below.

Conventionally, LDPC codes are defined by three parameters K, M and N:
K corresponds to the size of the source data, for example in terms of number of payload bits if considering binary data,
M corresponds to the size of the redundancy data, for example in terms of number of redundancy bits if considering binary data, and
N corresponds to the size of the data coming from the LDPC encoder, for example in terms of number of payload bits and redundancy bits.
   The coding rate is conventionally given by R=K/N, with the relationship N=K+M.

An LDPC code may in particular be defined by a parity matrix H, which gives the parity relationships between the source data and the redundancy data.

One example of a parity matrix H is given in FIG. 2.

Values equal to “1” in the parity matrix H correspond to the connections (parity equation) between the payload data and the redundancy data. The greater the number of connections (that is to say instances of “1” in the parity matrix H), the greater the complexity of the decoder will be.

By way of illustration, following the example of the parity matrix H in FIG. 2, the parity equation in the first row gives the first redundancy datum r(0):

$$r ( 0 ) = b ( 0 ) ⊕ b ( 1 ) ⊕ b ( 2 ) ⊕ b ( 3 ) ⊕ b ( 4 ) ⊕ b ( 6 ) ⊕ b ( 7 ) ⊕ b ( 9 ) ⊕ b ( 10 ) ⊕ b ( 11 ) ⊕ b ( 12 ) ⊕ b ( 13 )$$

$$with :$$

$$b ( i ) = 0 or 1 , and$$

$$⊕ the exclusive or operation .$$

In document ETSI TS 138 212 V15.2.0, the 3GPP standardization consortium defined two base structures or matrices BG1 and BG2 (base graph) enabling construction of 104 parity matrices H (52 matrices constructed from the base matrix BG1 and 52 matrices constructed from the base matrix BG2).

For example, for 5G, the size of the base matrices BG1 and BG2 is:

$$BG 1 : K = 22 , M = 46 , N = 68$$

$$BG 2 : either K = 6 , M = 26 , N = 32 , or K = 8 , M = 34 , N = 42 , or$$

$$K = 9 , M = 38 , N = 47 , or K = 10 , M = 42 , N = 52 .$$

The parity matrices H are obtained from the base matrices BG1 or BG2, from an expansion factor Z and a circular rotation of a diagonal matrix. Such a construction is known as a protograph.

According to this technique, a parity matrix H of size M.Z×N.Z is obtained by replacing each non-null element of the base matrix BG1 or BG2 with a diagonal matrix of size Z×Z to which a circular rotation V (which is not necessarily the same for all non-null elements of the base matrix) has been applied.

One advantage of this family of LDPC encoders is that of easily obtaining all parity matrices H while at the same time limiting memory usage.

For example, for an expansion factor Z=8 and a circular rotation V=2, a non-null element of the base matrix BG1 or BG2 is replaced with the following matrix:

$$[ \begin{matrix}0 & 0 & 1 & 0 & 0 & 0 & 0 & 0 \\ 0 & 0 & 0 & 1 & 0 & 0 & 0 & 0 \\ 0 & 0 & 0 & 0 & 1 & 0 & 0 & 0 \\ 0 & 0 & 0 & 0 & 0 & 1 & 0 & 0 \\ 0 & 0 & 0 & 0 & 0 & 0 & 1 & 0 \\ 0 & 0 & 0 & 0 & 0 & 0 & 0 & 1 \\ 1 & 0 & 0 & 0 & 0 & 0 & 0 & 0 \\ 0 & 1 & 0 & 0 & 0 & 0 & 0 & 0\end{matrix} ]$$

According to document ETSI TS 138 212 V15.2.0, for each base matrix BG1 or BG2, it is thus possible to construct 52 matrices, which are classified into eight subfamilies according to the value of the expansion factor Z (between 2 and 384), according to the “ils” index:

| ils index | Expansion factor Z |
|---|---|
| 0 | 2, 4, 8, 16, 32, 128, 256 |
| 1 | 3, 6, 12, 24, 48, 96, 192, 384 |
| 2 | 5, 10, 20, 40, 80, 160, 320 |
| 3 | 7, 14, 28, 56, 112.224 |
| 4 | 9, 18, 36, 72, 144.288 |
| 5 | 11, 22, 44, 88, 176.352 |
| 6 | 13, 26, 52, 104, 208 |
| 7 | 15, 30, 60, 120, 240 |

It is thus possible to code blocks of source data of size K.Z, ranging from 12 bits (from the base matrix BG2 with K=6 and the minimum expansion factor Z=2) to 8448 bits (from the base matrix BG1 with K=22 and the maximum expansion factor Z=384).

The choice between using the base matrix BG1 or BG2 is made according to the size of the source data to be coded K.Z and the desired coding rate R. Thus, as illustrated in FIG. 3, the base matrix BG1 is mainly used for high coding rates and large source data sizes. These two base matrices are in particular designed to cover the various uses of 5G, which may require a high data rate and/or high reliability (robustness).

Furthermore, according to the 5G standard, the first two columns of the base matrix BG1 or BG2 are deleted before transmission, resulting in the base rates being R_{BG1}=K/(N−2)=22/66=⅓ and R_{BG2}=10/50=⅕, respectively.

It should also be noted that the base matrices BG1 or BG2 used to construct the parity matrix H of an LDPC code according to the 5G standard may be represented in the form of six sub-matrices A, B, 0, C, D and I, as described in the document “High Area-Efficient Parallel Encoder with compatible architecture for 5G LDPC codes”, Y. Zhu et al., and illustrated in FIG. 4:

$$[ \begin{matrix}A & B & 0 \\ C & D & I\end{matrix} ]$$

with:
A a kernel matrix of size 4×K
B a matrix having at least one double diagonal of size 4×4
C an extension matrix of size (M−4)×K
D a prolongation matrix of size (M−4)×4
0 a null matrix of size (N−K−4)×4
I an identity matrix of size (M−4)×(N−K−4).

Although LDPC codes are recognized for their ability to guarantee high data-rate transmissions, in particular by virtue of the possibility of parallelizing operations in the decoder, one drawback of these codes is the complexity associated with decoding. Indeed, the greater the number of decoding iterations, the greater the number of operations to be carried out at reception, and the more resources they consume. The decoding block may thus use up to 90% of the resources of the receiver. It may be considered to be the most energy-intensive part of the physical layer, in particular for 5G.

There is therefore a need for a novel coding technique that seeks to reduce the energy consumption of the decoder.

### SUMMARY

The invention proposes a novel solution in the form of a method for coding at least one block of K.Z source data, delivering at least one codeword of size N.Z formed from the K.Z source data and from M.Z redundancy data, N=K+M, with Z an integer expansion factor, Z≥1.

The method according to the invention implements a step of coding said K.Z source data using a parity matrix H of size (M.Z×N.Z) obtained from a base matrix BG′ of size M×N, by replacing each element of said base matrix BG′ with an expansion matrix of size Z×Z,

said base matrix BG′ being expressed in the form:

$${BG}^{′} = [ \begin{matrix}A & B & 0 \\ C & D & I\end{matrix} ]$$

with:
A a kernel matrix of size J×K
B a matrix having at least one double diagonal of size J×J
C an extension matrix of size (M−J)×K
D a prolongation matrix of size (M−J)×J
0 a null matrix of size (N−K−J)×J
I an identity matrix of size (M−J)×(N−K−J).

According to the invention, said extension matrix C comprises at least two blocks of rows, each comprising a different number of rows, equal to a prime number or to the square of a prime number, each block of rows comprising at least one occurrence of a diagonal matrix.

In other words, the extension matrix C comprises at least a first block of L1 rows comprising one or more diagonal matrices of size L1×L1 and a second block of L2 rows comprising one or more diagonal matrices of size L2×L2, with L1+L2, L1 and L2 being prime numbers or squares of prime numbers.

The number of rows per block (which also corresponds to the size of the diagonals) is thus chosen from the prime numbers (2, 3, 5, 7, 11, 13, etc.) or the squares of prime numbers (4, 9, 25, etc.). It is thus sought to avoid repetition of the same pattern/of a diagonal matrix of same size in the various blocks of rows, so as to obtain an independence between the rows of the extension matrix C and to avoid, or at the very least limit, short cycles. It is also sought to distribute the non-null elements of the extension matrix C over the various rows and/or columns of the extension matrix C.

The proposed solution seeks in particular to improve the performance of error correcting codes, in particular of the LDPC decoder, by reducing the number of iterations of the decoder, and therefore energy consumption.

In particular, the coded data (codeword formed from the K.Z source data and M.Z redundancy data) may be stored in a memory and/or transmitted from a transmitter to a receiver, via a transmission channel.

According to one particular embodiment, at least one of said blocks of rows comprises at least two occurrences of said diagonal matrix.

By choosing the size of the diagonals (for example L1 and L2), it is possible to make the number of connections per row vary. For this purpose, it should be recalled that the greater the number of connections (that is to say of non-null elements in the base matrix, and consequently in the parity matrix H), the greater the complexity of the decoder will be. It is therefore sought, according to one embodiment, to achieve a compromise between the number of connections and decoding performance.

According to one particular embodiment, for at least one of said blocks of rows, said extension matrix C comprises a portion of said diagonal matrix, and said prolongation matrix D comprises the prolongation of said portion.

In other words, the matrix formed by said extension matrix C and said prolongation matrix D comprises at least one complete pattern representing said diagonal matrix and possibly a partial pattern.

According to one particular embodiment, the number of non-null elements per column and/or per row with respect to the total number of elements per column and/or per row in said kernel matrix A, excluding the first two columns, is between 50 and 100%.

In particular, the number of non-null elements per column and/or per row with respect to the total number of elements per column and/or per row in said kernel matrix A, excluding the first two columns, is between 75 and 100%.

The kernel matrix A thus has a large number of connections per row and/or per column, compared to the rest of the matrix BG′, thereby making it possible to recover the source data at decoding. For the 5G standard, the kernel matrix A has for example of the order of 3K/4 non-null elements per row.

According to one particular embodiment, the first two columns of the kernel matrix A and/or of said extension matrix C comprise an alternation of non-null elements and null elements in each row and each column.

What is thus sought is an equal distribution of the connections in the first two columns of the kernel matrix A and/or of said extension matrix C, with a quincunx structure. As indicated in the preamble, these first two columns might not be transmitted, in particular in 5G.

According to one particular embodiment J=4, K=22 and M=46.

The base matrix BG′ thus has a format similar to the matrix BG1 with a decomposition into six sub-matrices (A, B, C, D, 0 and I) and a size identical to the base matrix BG1. It may therefore be used in any system compatible with the 5G standard.

According to one particular embodiment, said kernel matrix A is equal to:

| | | | | | | | | | | | | | | | | | | | | | |
|---|---|---|---|---|---|---|---|---|---|---|---|---|---|---|---|---|---|---|---|---|---|
| V0 | | V0 | V1 | V3 | V4 | V3 | V2 | | V1 | V1 | V1 | | V1 | V4 | V0 | V4 | V2 | | V2 | V3 | V2 |
| | V2 | V2 | V2 | V3 | | V0 | | V0 | | V3 | V4 | V3 | V0 | | V1 | V2 | V1 | V0 | V3 | V4 | V0 |
| V1 | | V4 | V0 | V4 | | V0 | V2 | | V2 | | | V0 | | V0 | | V3 | V4 | V3 | | | V1 |
| | V0 | V4 | V1 | V2 | V1 | | V3 | V4 | V0 | V4 | | | V2 | V2 | V2 | | | V0 | V0 | V0 | |

said matrix B having at least one double diagonal is equal to:

| | | | |
|---|---|---|---|
| V1 | V0 | | |
| V0 | V0 | V0 | |
| | | V0 | V0 |
| V1 | | | V0 |

said extension matrix C is equal to:

| | | | | | | | | | | | | | | | | | | | | | |
|---|---|---|---|---|---|---|---|---|---|---|---|---|---|---|---|---|---|---|---|---|---|
| V0 | | V3 | | | | V0 | | | | V1 | | | | V2 | | | | V3 | | | |
| V3 | | | V1 | | | | V2 | | | | V3 | | | | V4 | | | | V1 | | |
| V1 | | | | V3 | | | | V4 | | | | V1 | | | | V0 | | | | V3 | |
| V3 | | | | | V1 | | | | V2 | | | | V3 | | | | V2 | | | | V1 |
| | V0 | V2 | | | | | V3 | | | | | V4 | | | | | V1 | | | | |
| V4 | | | V4 | | | | | V1 | | | | | V0 | | | | | V3 | | | |
| | V1 | | | V0 | | | | | V3 | | | | | V2 | | | | | V1 | | |
| | V3 | | | | V2 | | | | | V1 | | | | | V4 | | | | | V3 | |
| V0 | | | | | | V4 | | | | | V3 | | | | | V0 | | | | | V1 |
| | V4 | V1 | | | | | | | V0 | | | | | | | V3 | | | | | |
| V4 | | | V3 | | | | | | | V2 | | | | | | | V1 | | | | |
| | V4 | | | V1 | | | | | | | V4 | | | | | | | V3 | | | |
| | V0 | | | | V3 | | | | | | | V0 | | | | | | | V1 | | |
| | V2 | | | | | V1 | | | | | | | V2 | | | | | | | V3 | |
| V1 | | | | | | | V3 | | | | | | | V4 | | | | | | | V1 |
| | V1 | | | | | | | V1 | | | | | | | V0 | | | | | | |
| V1 | | V3 | | | | | | | | | V2 | | | | | | | | | V1 | |
| | V3 | | V1 | | | | | | | | | V4 | | | | | | | | | V3 |
| | V1 | | | V3 | | | | | | | | | V0 | | | | | | | | |
| V1 | | | | | V1 | | | | | | | | | V2 | | | | | | | |
| | V0 | | | | | V3 | | | | | | | | | V4 | | | | | | |
| | V4 | | | | | | V1 | | | | | | | | | V0 | | | | | |
| | V4 | | | | | | | V3 | | | | | | | | | V2 | | | | |
| V0 | | | | | | | | | V1 | | | | | | | | | V4 | | | |
| | V3 | | | | | | | | | V3 | | | | | | | | | V0 | | |
| V3 | | V1 | | | | | | | | | | | V4 | | | | | | | | |
| | V2 | | V3 | | | | | | | | | | | V0 | | | | | | | |
| V1 | | | | V1 | | | | | | | | | | | V2 | | | | | | |
| | V2 | | | | V3 | | | | | | | | | | | V4 | | | | | |
| V2 | | | | | | V1 | | | | | | | | | | | V0 | | | | |
| V3 | | | | | | | V3 | | | | | | | | | | | V2 | | | |
| V0 | | | | | | | | V1 | | | | | | | | | | | V4 | | |
| | V3 | | | | | | | | V3 | | | | | | | | | | | V0 | |
| V4 | | | | | | | | | | V1 | | | | | | | | | | | V2 |
| V2 | | | | | | | | | | | V3 | | | | | | | | | | |
| V2 | | | | | | | | | | | | V1 | | | | | | | | | |
| | V1 | V0 | | | | | | | | | | | | | V3 | | | | | | |
| V3 | | | V2 | | | | | | | | | | | | | V1 | | | | | |
| | V1 | | | V4 | | | | | | | | | | | | | V3 | | | | |
| | V4 | | | | V0 | | | | | | | | | | | | | V1 | | | |
| | V4 | | | | | V2 | | | | | | | | | | | | | V3 | | |
| V2 | | | | | | | V4 | | | | | | | | | | | | | V1 | |

said prolongation matrix D is equal to:

| | | | |
|---|---|---|---|
| V4 | V0 | V2 | V2 |
| | V0 | | |
| | | V2 | |
| | | | V4 |
| V1 | | | |
| | V3 | | |
| | | V1 | |
| | | | V3 |
| | V2 | | |
| | | V4 | |
| | | | V0 |
| V3 | | | |
| V1 | | | |
| | V3 | | |
| | | V1 | |
| | | | V3 |
| | | V1 | |
| | | | V3 |
| V4 | | | |
| | V0 | | |

The empty elements of the matrices above correspond to null values.

According to this embodiment:
each empty or null element of said base matrix BG′ is replaced with a null matrix of size Z×Z,
each non-null element of said base matrix BG′ is replaced with a circular permutation matrix obtained by applying a circular rotation Vi to an identity matrix of size Z×Z, such that:

| | Circular rotation Vi |
|---|---|
| if Z belongs to | V1 = 0 + 4y, y ∈ [0:63] |
| {2, 4, 8, 16, 32, 128, 256}: | V1 = 1 + 4y, y ∈ [0:63] |
| | V2 = 2 + 4y, y ∈ [0:63] |
| | V3 = 3 + 4y, y ∈ [0:63] |
| | V4 = 0 + 4y, y ∈ [0:63] |
| if Z belongs to | V1 = 0 + 5x + 6y, x ∈ [0:1] and y ∈ [0:63] |
| {3, 6, 12, 24, 48, 96, 192, 384}: | V1 = 1 + 6y, y ∈ [0:63] |
| | V2 = 2 + 6y, y ∈ [0:63] |
| | V3 = 3 + 6y, y ∈ [0:63] |
| | V4 = 4 + 6y, y ∈ [0:63] |
| if Z belongs to | V1 = 0 + 5y, y ∈ [0:63] |
| {5, 10, 20, 40, 80, 160, 320}: | V1 = 1 + 5y, y ∈ [0:63] |
| | V2 = 2 + 5y, y ∈ [0:63] |
| | V3 = 3 + 5y, y ∈ [0:63] |
| | V4 = 4 + 5y, y ∈ [0:63] |
| if Z belongs to | V1 = 0 + 5x + 7y, x ∈ [0:1] and y ∈ [0:31] |
| {7, 14, 28, 56, 112.224}: | V1 = 1 + 5x + 7y, x ∈ [0:1] and y ∈ [0:31] |
| | V2 = 2 + 7y, y ∈ [0:31] |
| | V3 = 3 + 7y, y ∈ [0:31] |
| | V4 = 4 + 7y, y ∈ [0:31] |
| if Z belongs to | V1 = 0 + 5x + 9y, x ∈ [0:1] and y ∈ [0:31] |
| {9, 18, 36, 72, 144.288}: | V1 = 1 + 5x + 9y, x ∈ [0:1]and y ∈ [0:31] |
| | V2 = 2 + 5x + 9y, x ∈ [0:1] and y ∈ [0:31] |
| | V3 = 3 + 5x + 9y, x ∈ [0:1] and y ∈ [0:31] |
| | V4 = 4 + 9y, y ∈ [0:31] |
| if Z belongs to | V1 = 0 + 5x + 11y, x ∈ [0:2] and y ∈ [0:31] |
| {11, 22, 44, 88, 176.352}: | V1 = 1 + 5x + 11y, x ∈ [0:1] and y ∈ [0:31] |
| | V2 = 2 + 5x + 11y, x ∈ [0:1] and y ∈ [0:31] |
| | V3 = 3 + 5x + 11y, x ∈ [0:1] and y ∈ [0:31] |
| | V4 = 4 + 5x + 11y, x ∈ [0:1] and y ∈ [0:31] |
| if Z belongs to | V1 = 0 + 5x + 13y, x ∈ [0:2] and y ∈ [0:15] |
| {13, 26, 52, 104, 208}: | V1 = 1 + 5x + 13y, x ∈ [0:2] and y ∈ [0:15] |
| | V2 = 2 + 5x + 13y, x ∈ [0:2] and y ∈ [0:15] |
| | V3 = 3 + 5x + 13y, x ∈ [0:1] and y ∈ [0:15] |
| | V4 = 4 + 5x + 13y, x ∈ [0:1] and y ∈ [0:15] |
| if Z belongs to | V1 = 0 + 5x + 15y, x ∈ [0:2] and y ∈ [0:15] |
| {15, 30, 60, 120, 240}: | V1 = 1 + 5x + 15y, x ∈ [0:2] and y ∈ [0:15] |
| | V2 = 2 + 5x + 15y, x ∈ [0:2] and y ∈ [0:15] |
| | V3 = 3 + 5x + 15y, x ∈ [0:2] and y ∈ [0:15] |
| | V4 = 4 + 5x + 15y, x ∈ [0:2] and y ∈ [0:15] |

with x and y random variables.

In another embodiment, the invention relates to a device for coding at least one block of K.Z source data, delivering at least one codeword of size N.Z formed from said K.Z source data and from M.Z redundancy data, N=K+M, with Z an integer expansion factor, Z≥1, comprising at least one processing unit configured to code said K.Z source data using a parity matrix H of size (M.Z×N.Z), said parity matrix H being obtained from a base matrix BG′ of size M×N as described above.

Such a coding device, also called an encoder, is in particular designed to implement the coding method described above. It may of course comprise the various features relating to the method according to the invention, which may be combined or taken on their own. The features and advantages of the encoder are thus the same as those of the method described above. They are therefore not described in more detail.

The invention also relates to one or more computer programs comprising instructions for implementing a method as described above when these one or more programs are executed by at least one processor.

The invention also relates to a computer-readable information medium comprising instructions of a computer program as mentioned above.

### BRIEF DESCRIPTION OF THE DRAWINGS

Other features and advantages of the invention will become more clearly apparent from reading the following description of one particular embodiment, given by way of simple illustrative and non-limiting example, and the appended drawings, in which:

FIG. 1 illustrates a transmitter in a conventional digital transmission chain;

FIG. 2 shows one example of a parity matrix H for an LDPC code;

FIG. 3 illustrates selection criteria for the base matrix BG1 or BG2;

FIG. 4 illustrates the decomposition of the base matrix BG1 or BG2 into sub-matrices;

FIG. 5 shows the main steps implemented by a coding method according to one embodiment of the invention;

FIG. 6A and FIG. 6B illustrate the structure of the matrix BG1;

FIG. 7A and FIG. 7B illustrate the concept of a cycle;

FIGS. 8 to 15 show various structures of the matrices A, C and/or D that make it possible to optimize the base matrix BG′, according to one embodiment of the invention;

FIGS. 16 and 17 illustrate curves of the performance displayed by an LDPC decoder when decoding a codeword obtained according to an embodiment of the invention;

FIG. 18 shows the simplified structure of an encoder implementing a coding method according to one embodiment of the invention.

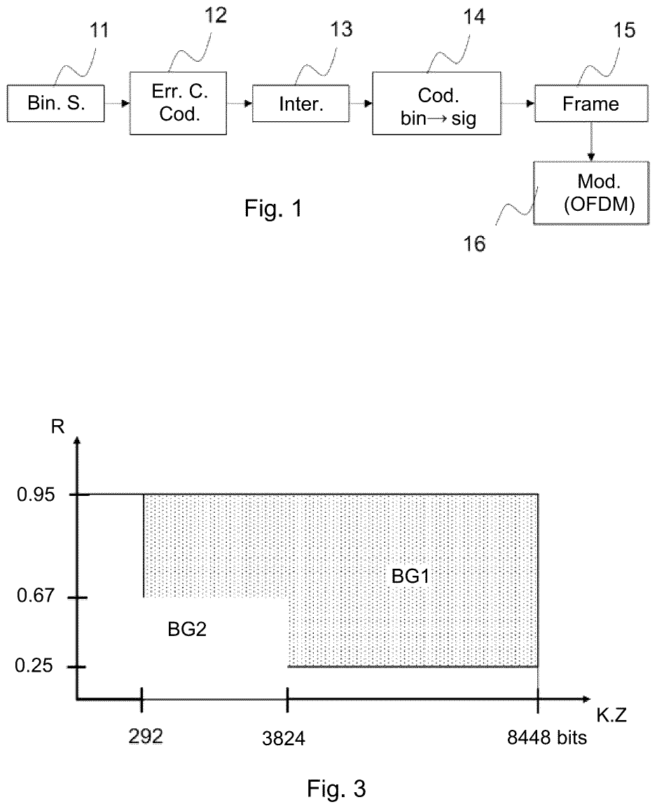

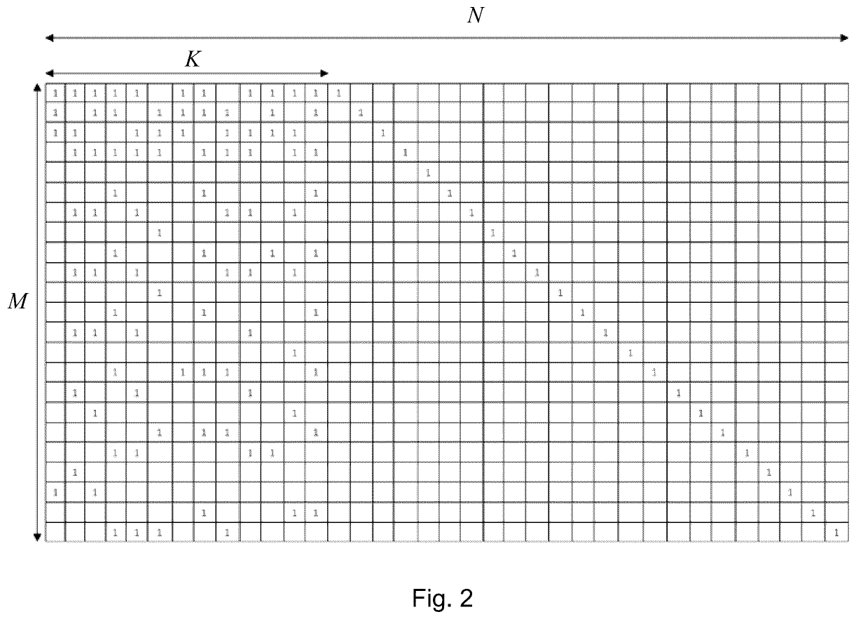

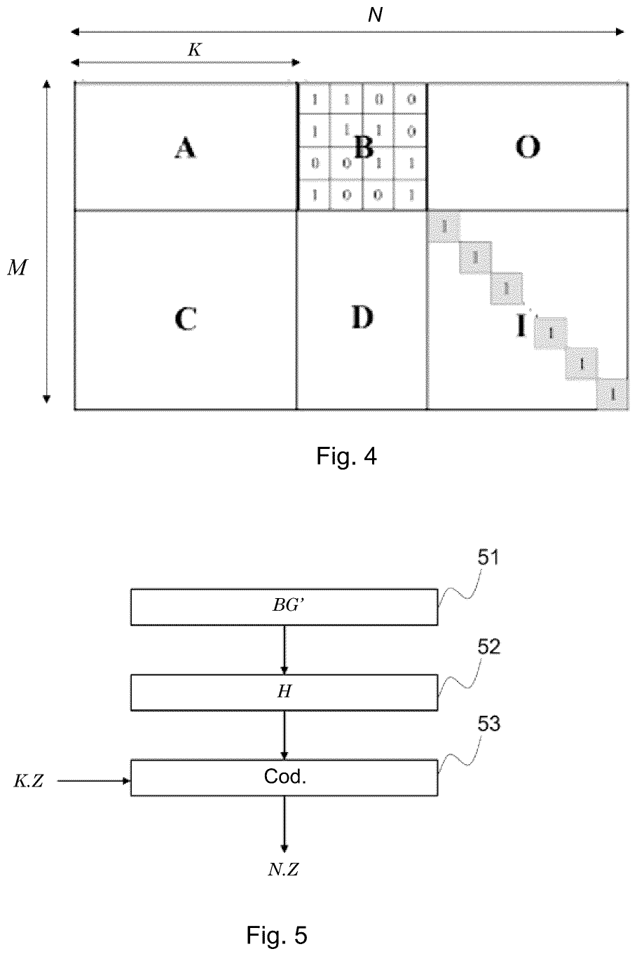

### DETAILED DESCRIPTION OF CERTAIN ILLUSTRATIVE EMBODIMENTS

### General Principle

The general principle of the invention is based on cleverly distributing connections (that is to say non-null elements) in a base matrix BG′, seeking to distribute the connections substantially uniformly and/or to limit the number of short cycles. As a result, a parity matrix H obtained from the base matrix BG′ has a particular structure. Such a structure makes it possible to improve the performance of error correcting codes, in particular by reducing decoding complexity.

FIG. 5 illustrates the main steps of a coding method according to one embodiment of the invention.

In a first step 51, the base matrix BG′ of size M×N is obtained.

Such a base matrix BG′ may be decomposed into six sub-matrices A, B, 0, C, D, I and expressed in the form:

$${BG}^{′} = [ \begin{matrix}A & B & 0 \\ C & D & I\end{matrix} ]$$

with:
A a kernel matrix of size J×K
B a matrix having at least one double diagonal of size J×J
C an extension matrix of size (M−J)×K
D a prolongation matrix of size (M−J)×J
0 a null matrix of size (N−K−J)×J
I an identity matrix of size (M−J)×(N−K−J)

In particular, the extension matrix C has a particular structure and comprises at least two blocks of rows, each comprising a different number of rows, equal to a prime number or to the square of a prime number, each block of rows comprising at least one occurrence of a diagonal matrix.

In a second step 52, a parity matrix H is obtained from the base matrix BG′. To this end, each element of the base matrix BG′ is replaced with an expansion matrix of size Z×Z, with Z an integer expansion factor, Z≥1. More specifically, each null element of the base matrix BG′ is replaced by a null matrix of size Z×Z, and each non-null element of the base matrix BG′ is replaced by a circular permutation matrix, obtained by applying a circular rotation Vi to an identity matrix of size Z×Z. In a third step 53, at least one block of K.Z source data is coded using the parity matrix H of size (M.Z×N.Z), so as to obtain at least one codeword of size N.Z formed from K.Z source data and M.Z redundancy data, N=K+M.

Such a codeword may in particular be stored in a memory of the encoder or transmitted by a transmitter to a receiver.

In one particular embodiment, the number of non-null elements per column in the matrix formed from the kernel matrix A and the extension matrix C, excluding the first two columns, is between β−3 and β+3, with B an integer. In the matrix formed from the extension matrix C and from the prolongation matrix D, the number of non-null elements per row, excluding the first two columns, is between α−4 and α+4, with a an integer.

It is thereby sought to distribute the number of connections per column and/or per row uniformly in the base matrix BG′.

For example, in 5G, β is between 7 and 10, and the number of non-null elements per column in the matrix formed from the kernel matrix A and the extension matrix C, excluding the first two columns, is between 5 and 13, for example between 7 and 10.

According to another example, the number of non-null elements per column in the extension matrix C, excluding the first two columns, is between 2 and 8, for example equal to 5 or 6.

According to yet another example, the number of non-null elements per column in said kernel matrix A, excluding the first two columns, is between 2 and 4, for example equal to 3.

For example, in 5G, α is between 5 and 8, and the number of non-null elements per row in the matrix formed from the extension matrix C and the prolongation matrix D is between 1 and 12, for example between 2 and 9.

According to another example, the number of non-null elements per row in the extension matrix C is between 1 and 7.

In particular, if J=4, K=22 and M=46, the base matrix BG′ has a size identical to the base matrix BG1, and may be used in any system using the 5G standard.

### Base Matrix BG1

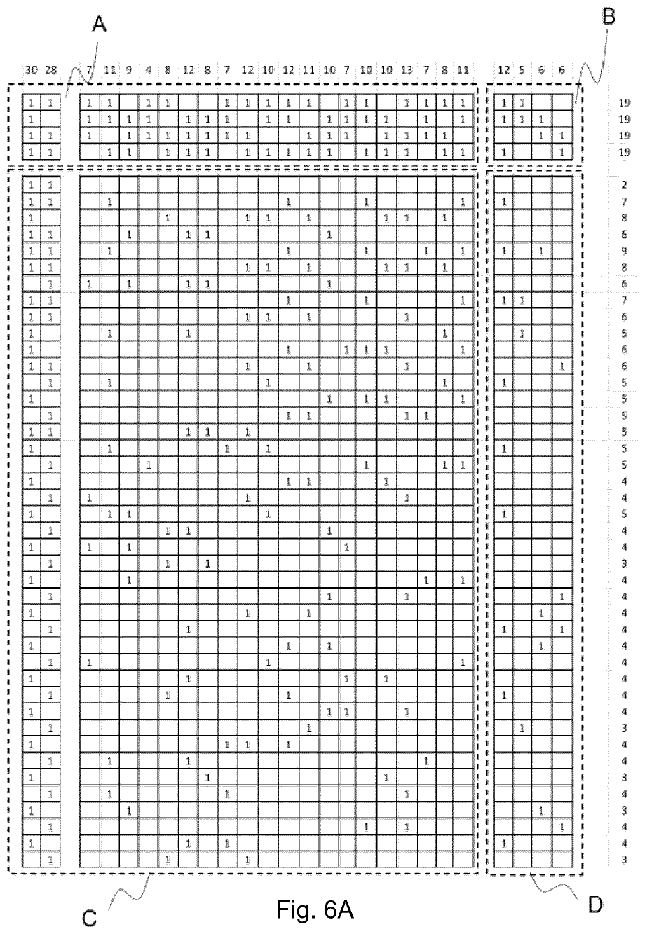

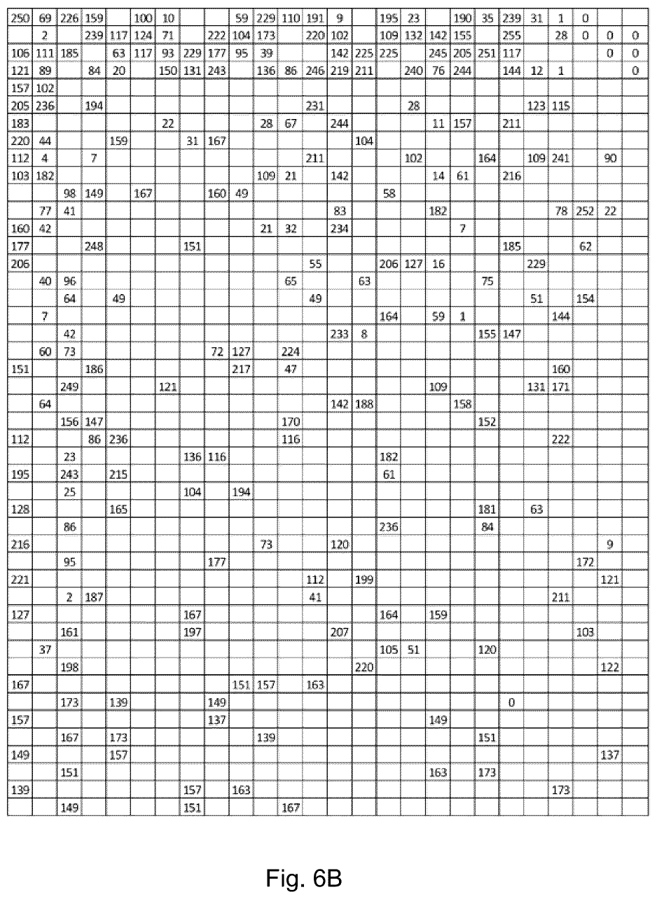

In order to better understand the invention, FIG. 6A recalls the structure of the base matrix BG1 as defined in document ETSI TS 138 212 V15.2.0, formed from the matrices A, B, C and D. The sub-matrices I and 0 are omitted for the sake of simplification.

The “1” elements of the base matrix BG1 represent the connections of the various parity equations. The number of connections per column and per row has been added to FIG. 6A.

Thus, the first column of the matrices A and C comprises 30 connections, the second column comprises 28 connections, the third column comprises 7 connections, etc.

The first column of the matrices B and D comprises 12 connections, the second column comprises 5 connections, etc.

The first four rows of the matrices A and B each comprise 19 connections.

The first row of the matrices C and D comprises 2 connections, the second row comprises 7 connections, etc.

If the null matrix 0 and identity matrix I are not taken into account, the minimum number of connections per row is 2 and the maximum number of connections per row is 19. The minimum number of connections per column is 4 and the maximum number of connections per column is 30. There is therefore a large disparity in the number of connections per row and/or per column in the matrix BG1.

The kernel matrix A has, proportionally, a large number of connections, that is to say a large number of non-null elements, because it is the kernel of the matrix BG1. This enables the decoder to recover these data at reception. It should also be noted that the first two columns of the matrix BG1, which correspond to the non-transmitted data, also have a large number of instances of “1”.

The upper part of the matrix BG1 also has more connections than its lower part, thereby making it possible to guarantee good performance for high rates. Indeed, the lower part of the matrix BG1 may be punctured so as to obtain the desired rate. It is therefore preferable to choose the connections in the upper part of the matrix BG1.

By way of example, FIG. 6B illustrates the circular rotation factors V for the matrix BG1 from FIG. 6A, for an expansion factor Z=256.

The parity matrix H is constructed by replacing each non-null element of the matrix BG1 with an identity matrix of size Z×Z, and by applying a circular rotation V according to the factors illustrated in FIG. 6B. Thus, the “1” element in the first row/first column of the matrix BG1 from FIG. 6A is replaced with an identity matrix of size 256×256, to which a circular rotation V=250 is applied. The “1” element in the first row/second column of the matrix BG1 from FIG. 6A is replaced with an identity matrix of size 256×256, to which a circular rotation V=69 is applied, and so on.

### Base Matrix BG′

The position of the connections in the base matrix BG1, along with the rotation factors to be used, are specified in the 3GPP 5G standard. However, as indicated previously, it remains desirable to improve the performance of error correcting codes, in particular by reducing decoding complexity, for example by reducing the number of connections.

A base matrix BG′ that seeks to reduce decoding complexity is therefore proposed below. Novel structures of the connections are thus proposed, according to various embodiments of the invention. According to the embodiment under consideration, such structures are efficient and/or easy to reproduce as a function of the dimensions of the parity matrix H.

According to one particular embodiment, the structure of the base matrix BG′ is defined so as to have a small disparity in the number of connections per row and/or per column. Indeed, if considering an LDPC encoder for example, it will be recalled that LDPC decoding is based on the bases of probabilities of having transmitted a value equal to “1” or “O”. It is therefore desirable to distribute the number of connections uniformly, so that the number of connections in a row, and especially in a column, is substantially constant or equally distributed.

According to another particular embodiment, the structure of the base matrix BG′ is defined so as to limit the number of short cycles, and if possible to avoid short cycles (girth). Indeed, such short cycles limit the performance of error correcting codes, in particular LDPC codes, especially for values K of small sizes, for example of the order of 256 bits or less.

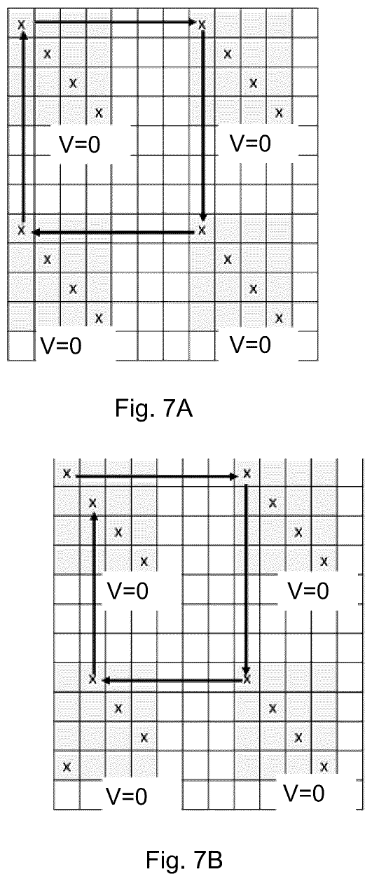

To better understand this principle, FIGS. 7A and 7B illustrate the phenomena of loops with an expansion factor Z=4. According to FIG. 7A, an expansion factor Z=4 with the same rotation factor V=0 is applied to the “1” elements located at the positions (i,j), (i+7,j), (i, j+7) and (i+7,j+7) . . . . This results in a loop, illustrated by the arrows. According to FIG. 7B, an expansion factor Z=4 with the same rotation factor V=0 is applied to the “1” elements located at the positions (i, j), (i+7,j) and (i+7,j+7), and a rotation factor V=1 is applied to the element located at the position (i, j+7). In this case, there is no loop. Changing rotation factor of one of the elements of the matrix therefore makes it possible to eliminate the loops.

A presentation is given below of various solutions that make it possible to obtain a small disparity in the number of connections per row and/or per column of the base matrix BG′ and/or to limit (or even avoid) short cycles.

### Optimizing the Kernel Matrix A

According to a first example, it is possible to distribute the connections equally in the kernel matrix A, while at the same time seeking to have a large number of connections as defined in the 5G standard.

For example, in the kernel matrix A, the number of non-null elements per column, excluding the first two columns, is between 1 and J.

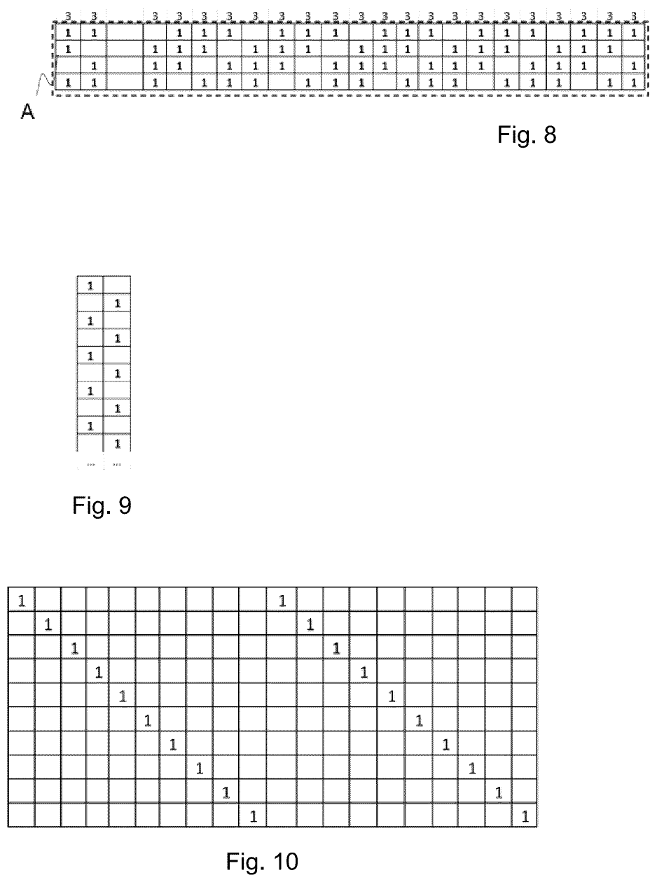

FIG. 8 illustrates one example of a kernel matrix A, in which the number of non-null elements per column is constant and equal to 3.

Optimizing the First Two Columns of the Kernel Matrix a and/or of the Extension Matrix C

According to a second example, the first two columns (which are generally not transmitted) may be chosen so as to guarantee a good distribution of the connections.

For example, the first two columns of the kernel matrix A and/or of the extension matrix C comprise an alternation of non-null elements and null elements in each row and each column. In other words, the connections are distributed in a quincunx, as illustrated in FIG. 9.

### Optimizing the Extension Matrix C

According to a third example, it is possible to distribute the connections equally in the extension matrix C.

The extension matrix C is generally the largest by size. For the base matrix BG1, for example, the extension matrix C, excluding its first two columns, has a size 40×20.

According to this third example, the connections are distributed over diagonals so as to guarantee a good distribution of the connections.

For example, if a block of 10 rows and 20 columns is considered, as illustrated in FIG. 10, it is possible to have two occurrences of a diagonal matrix 10×10 in the block of 10 rows, i.e. two connections per row and one per column.

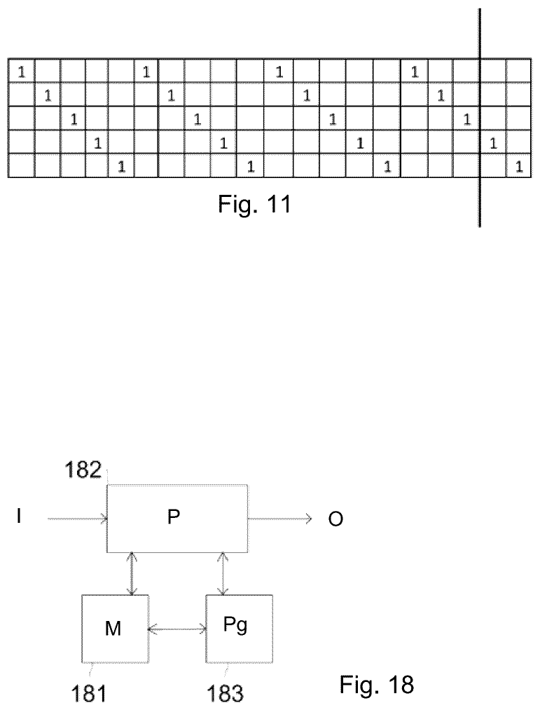

According to another example, if a block of 5 rows and 20 columns is considered, as illustrated in FIG. 11, it is possible to have four occurrences of a diagonal matrix 5×5 in the block of 5 rows, i.e. four connections per row and one per column.

It is thus possible to make the number of connections per row vary in accordance with the size of the diagonals or of the blocks of rows.

To guarantee an independence between the rows, and therefore avoid short cycles, the proposed solution is based on selection of a size for the diagonals that corresponds to prime numbers or squares of prime numbers. In particular, it is sought to select prime numbers or squares of prime numbers that avoid reproduction of the same patterns in the extension matrix C.

Thus, according to the invention, the extension matrix C comprises at least two blocks of rows, each comprising a different number of rows, equal to a prime number (2, 3, 5, 7, 11, 13 . . . ) or to the square of a prime number (4=22, 9=32), each block of rows comprising at least one occurrence of a diagonal matrix (i.e. at least one complete pattern).

In this way, all the parity equations are distinct from one another.

In particular, at least one of the blocks of rows comprises at least two occurrences of the diagonal matrix (i.e. at least two complete patterns).

The structure of the extension matrix C may in particular be prolonged in the prolongation matrix D. Thus, for at least one block of rows, the extension matrix C comprises a portion of a diagonal matrix, and the prolongation matrix D comprises the prolongation of the portion of the diagonal matrix. For example, returning to FIG. 11, if a block of 5 rows and 20 columns is considered, with the first 18 columns belonging to the extension matrix C and the last 2 columns belonging to the prolongation matrix D, the extension matrix C comprises three “complete” patterns, each corresponding to the diagonal matrix 5×5. The fourth pattern is partial and is prolonged in the prolongation matrix D. The matrix formed by the extension matrix C and prolongation matrix D comprises four “complete” patterns each corresponding to the diagonal matrix 5×5.

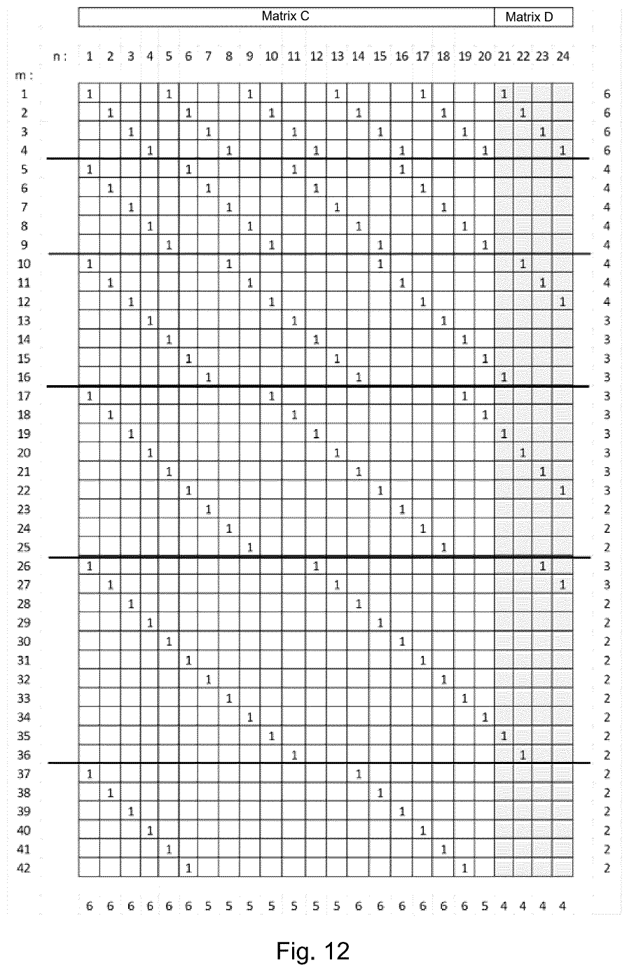

By way of example, FIG. 12 shows one example of a structure for the extension matrix C and prolongation matrix D that may be used in 5G. In this example, the extension matrix C has a size (M−J)×K=42×22 and the prolongation matrix D has a size (M−J)×J=42×4. The first two columns of the extension matrix C have not been illustrated.

As it is sought to select prime numbers that avoid reproduction of the same patterns for the extension matrix C, the prime numbers 2 and 3 are eliminated in this example. For example, it is possible to define a first block of rows with diagonal matrices of size 4, a second block of rows with diagonal matrices of size 5, a third block of rows with diagonal matrices of size 7, a fourth block of rows with diagonal matrices of size 9, a fifth block of rows with diagonal matrices of size 11, etc.

Denoting n the number of a column of the extension matrix C, with n ranging from 1 to (K−2) (if the first two columns of the extension matrix C are not taken into account), and m the number of a row of the extension matrix C, with m ranging from 1 to (M−J), the location of the connections can be obtained deterministically.

For example, for the rows of the extension matrix C, the location of the connections can be obtained via the following algorithm:

```
For m ranging from 1 to 4:
  For n ranging from 1 to (K − 2) :
    If (n mod 4) = m then BG′[m][n] = 1
For m ranging from 5 to 9:
  For n ranging from 1 to (K − 2) :
    If (n mod 5) = m then BG′[m][n] = 1
For m ranging from 10 to 16:
  For n ranging from 1 to (K − 2) :
    If (n mod 7) = m then BG′[m][n] = 1
For m ranging from 17 to 25:
  For n ranging from 1 to (K − 2) :
    If (n mod 9) = m then BG′[m][n] = 1
For m ranging from 26 to 36:
  For n ranging from 1 to (K − 2) :
    If (n mod 11) = m then BG′[m][n] = 1
For m ranging from 37 to (M − J) = 42:
  For n ranging from 1 to (K − 2) :
    If (n mod 13) = m then BG′[m][n] = 1
```

The prolongation matrix D allows the diagonal matrices to be extended.

FIG. 12 in particular illustrates the number of connections per row and per column for the extension matrix C and prolongation matrix D.

It may be seen that in the matrix formed from the extension matrix C and the prolongation matrix D, the number of non-null elements per row, excluding the first two columns, is between α−4 and α+4, with a an integer.

Adopting the context of 5G, a is for example between 5 and 8.

In the example illustrated in FIG. 12, the number of non-null elements per row in the matrix formed by the extension matrix C and the prolongation matrix D is between 2 and 6.

The number of non-null elements per column in the extension matrix C is for its part between 5 and 6, and in the prolongation matrix D equal to 4.

As the lower part of the extension matrix C and of the prolongation matrix D may be punctured, it is chosen to put the greater number of connections in the upper part of the extension matrix C and prolongation matrix D.

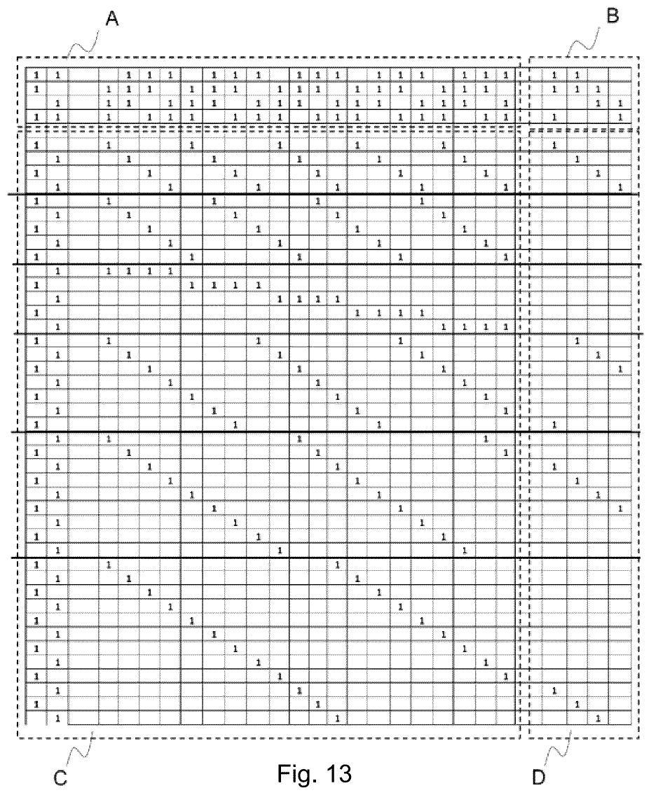

Another example of optimization of the extension matrix C (including the first two columns) and prolongation matrix D is illustrated in FIG. 13.

The proposed structure is slightly different, but the extension matrix C still comprises at least two blocks of rows, each comprising a different number of rows, equal to a prime number (2, 3, 5, 7, 11, 13 . . . ) or to the square of a prime number (4=22, 9=32), each block of rows comprising at least one occurrence of a diagonal matrix (i.e. at least one complete pattern).

It still has good properties in terms of connection distribution and/or reduction/elimination of short cycles.

In the example in FIG. 13 there is a first block of rows with diagonal matrices of size 4; a second block of rows with diagonal matrices of size 5; a third block of rows with in the first row non-null elements at positions 1 to 4 (ignoring the first two columns), in the second row non-null elements at positions 5 to 8, in the third row non-null elements at positions 9 to 12, in the fourth row non-null elements at positions 13 to 16, and in the fifth row non-null elements at positions 17 to 20; a fourth block of rows with diagonal matrices of size 7; a fifth block of rows with diagonal matrices of size 9, etc.

### Global Optimization of the Base Matrix BG′

In the examples above, the extension matrix C (excluding the first two columns) and prolongation matrix D are optimized so as to reduce short cycles.

However, if taking into account the matrix formed from the kernel matrix A, double diagonal matrix B, extension matrix C and prolongation matrix D proposed in the examples above, short cycles may remain.

Such short cycles may result for example from the structure proposed for the kernel matrix A or for the first two columns of the extension matrix C.

As illustrated in FIG. 7B, taking into account rotation factors makes it possible in particular to reduce, or even avoid, short cycles.

It is thus possible to increase the diversity of the base matrix BG′ and therefore to reduce the number of short cycles by taking into account rotation factors.

Adopting the context of the 5G standard, the expansion factor Z is at least equal to 2. This means that there are at least two possible rotation factors: a non-null element of the base matrix BG′ may be replaced with

$$[ \begin{matrix}1 & 0 \\ 0 & 1\end{matrix} ]$$

or a circular rotation V=0 or with

$$[ \begin{matrix}0 & 1 \\ 1 & 0\end{matrix} ]$$

for a circular rotation V=1.

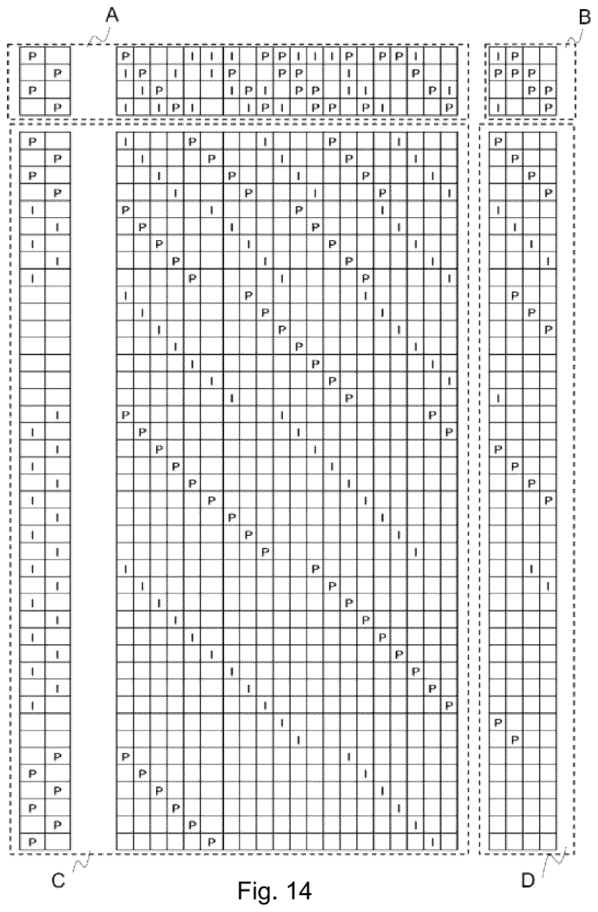

FIG. 14 shows one example of a structure for the matrices A, B, C and D, taking into account at least two distinct rotation factors—for example, an even rotation factor P and an odd rotation factor I.

In this example, the extension matrix C still comprises at least two blocks of rows, each comprising a different number of rows, equal to a prime number (2, 3, 5, 7, 11, 13 . . . ) or to the square of a prime number (4=2², 9=3²), each block of rows comprising at least one occurrence of a diagonal matrix (i.e. at least one complete pattern).

In addition, one block of rows is associated with at least two distinct rotation factors.

The structure illustrated in FIG. 14 in particular allows cycles to be reduced by reorganizing the rotation factors into even “P” and odd “I” values.

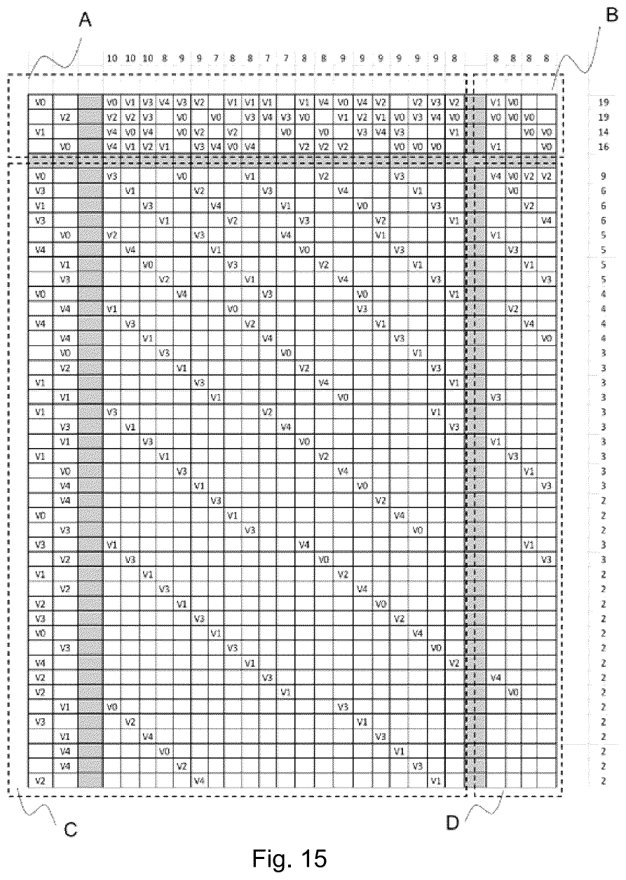

As illustrated in FIG. 15, it is possible to increase the number of rotation factors so as to increase the diversity of the base matrix BG′. For example, five rotation factors, denoted V0 to V4, are chosen. Of course, a different number of rotation factors may be chosen, thereby leading to a different structure for the matrices A, B, C and D.

It is possible in particular to define the equations that define the rotation factors V0 to V4 as a function of the “ils” index according to the 3GPP 5G standard.

| “ils” index | Circular rotation V |
|---|---|
| 0 | V0 = 0 + 4y, y ∈ [0:63] |
| | V1 = 1 + 4y, y ∈ [0:63] |
| | V2 = 2 + 4y, y ∈ [0:63] |
| | V3 = 3 + 4y, y ∈ [0:63] |
| | V4 = 0 + 4y, y ∈ [0:63] |
| 1 | V1 = 0 + 5x + 6y, x ∈ [0:1] and y ∈ [0:63] |
| | V1 = 1 + 6y, y ∈ [0:63] |
| | V2 = 2 + 6y, y ∈ [0:63] |
| | V3 = 3 + 6y, y ∈ [0:63] |
| | V4 = 4 + 6y, y ∈ [0:63] |
| 2 | V1 = 0 + 5y, y ∈ [0:63] |
| | V1 = 1 + 5y, y ∈ [0:63] |
| | V2 = 2 + 5y, y ∈ [0:63] |
| | V3 = 3 + 5y, y ∈ [0:63] |
| | V4 = 4 + 5y, y ∈ [0:63] |
| 3 | V1 = 0 + 5x + 7y, x ∈ [0:1] and y ∈ [0:31] |
| | V1 = 1 + 5x + 7y, x ∈ [0:1] and y ∈ [0:31] |
| | V2 = 2 + 7y, y ∈ [0:31] |
| | V3 = 3 + 7y, y ∈ [0:31] |
| | V4 = 4 + 7y, y ∈ [0:31] |
| 4 | V1 = 0 + 5x + 9y, x ∈ [0:1] and y ∈ [0:31] |
| | V1 = 1 + 5x + 9y, x ∈ [0:1]and y ∈ [0:31] |
| | V2 = 2 + 5x + 9y, x ∈ [0:1] and y ∈ [0:31] |
| | V3 = 3 + 5x + 9y, x ∈ [0:1] and y ∈ [0:31] |
| | V4 = 4 + 9y, y ∈ [0:31] |
| 5 | V1 = 0 + 5x + 11y, x ∈ [0:2] and y ∈ [0:31] |
| | V1 = 1 + 5x + 11y, x ∈ [0:1] and y ∈ [0:31] |
| | V2 = 2 + 5x + 11y, x ∈ [0:1] and y ∈ [0:31] |
| | V3 = 3 + 5x + 11y, x ∈ [0:1] and y ∈ [0:31] |
| | V4 = 4 + 5x + 11y, x ∈ [0:1] and y ∈ [0:31] |
| 6 | V1 = 0 + 5x + 13y, x ∈ [0:2] and y ∈ [0:15] |
| | V1 = 1 + 5x + 13y, x ∈ [0:2] and y ∈ [0:15] |
| | V2 = 2 + 5x + 13y, x ∈ [0:2] and y ∈ [0:15] |
| | V3 = 3 + 5x + 13y, x ∈ [0:1] and y ∈ [0:15] |
| | V4 = 4 + 5x + 13y, x ∈ [0:1] and y ∈ [0:15] |
| 7 | V1 = 0 + 5x + 15y, x ∈ [0:2] and y ∈ [0:15] |
| | V1 = 1 + 5x + 15y, x ∈ [0:2] and y ∈ [0:15] |
| | V2 = 2 + 5x + 15y, x ∈ [0:2] and y ∈ [0:15] |
| | V3 = 3 + 5x + 15y, x ∈ [0:2] and y ∈ [0:15] |
| | V4 = 4 + 5x + 15y, x ∈ [0:2] and y ∈ [0:15] |

with x and y random variables the interval of which is given in the above table.

The structure illustrated in FIG. 15 makes it possible in particular to reduce short cycles for small matrices, for example for K<256.

It is observed in particular that, in the matrix formed from the kernel matrix A and from the extension matrix C, the number of non-null elements per column, excluding the first two columns, is between β−3 and β+3, with B an integer. In the matrix formed from the extension matrix C and from the prolongation matrix D, the number of non-null elements per row, excluding the first two columns, is between α−4 and α+4, with a an integer.

Adopting the context of 5G, B is for example between 7 and 10 and a is between 5 and 8. In the example illustrated in FIG. 15, the number of non-null elements per column in the matrix formed from the kernel matrix A and from the extension matrix C is between 7 and 10, and the number of non-null elements per row in the matrix formed from the extension matrix C and from the prolongation matrix D is between 2 and 9.

The number of connections per row and/or per column is therefore relatively uniform.

### Obtaining a Parity Matrix

From the base matrix BG′ thus obtained, it is possible to obtain a parity matrix H by replacing each empty or null element of the base matrix BG′ with a null matrix of size Z×Z, and each non-null element of the base matrix BG′ with a circular permutation matrix obtained by applying a circular rotation Vi to an identity matrix of size Z×Z, i∈{0, 1, . . . }.

The parity matrix H thus obtained may be used by an encoder to code at least one block of K.Z source data.

### Performance Curves

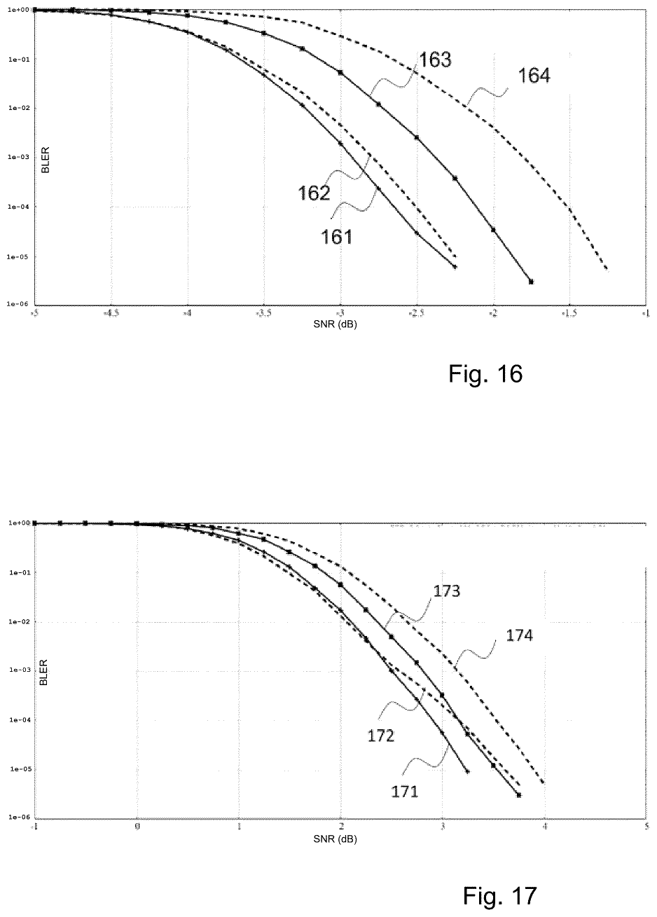

With reference to FIGS. 16 and 17, a description will now be given of the decoding performance obtained in terms of error rate (FER) as a function of signal-to-noise ratio (SNR in dB) for LDPC decoders, after coding of source data using a parity matrix obtained either from the base matrix BG1 as defined by the 3GPP for the 5G standard, or from a base matrix BG′ according to one embodiment of the invention (having the same size as the base matrix BG1 for the sake of comparison).

The performance obtained is, for code lengths of 330 bits (K=22, Z=15), a code rate of 1/3 in FIG. 16 and 3/4 in FIG. 17. According to this example, the decoder algorithm is a MinSum such as described in the document “A fully parallel LDPC decoder architecture using probabilistic minsum algorithm for high-throughput applications”, C.-C. Cheng et al., IEEE Trans. Circuits Syst. I, Reg. Papers, vol. 61, no. 9, pp. 2738-2746 September 2014, with an alpha parameter equal to 0.7, and operated in “reverse” mode. In such a reverse mode, the parity matrix is decoded from bottom to top, i.e. it is first sought to solve the parity equations obtained from the last rows of the parity matrix before those obtained from the first rows of the parity matrix. However, the use of “standard” decoding (from top to bottom) of the parity matrix, or of decoding in some other order, is also possible.

Curves 161 and 171 illustrate the decoding performance obtained using the base matrix BG′ after 20 iterations of the decoder. Curves 162 and 172 illustrate the decoding performance obtained using the base matrix BG1 after 20 iterations of the decoder.

Curves 163 and 173 illustrate the decoding performance obtained using the base matrix BG′ after 5 iterations of the decoder. Curves 164 and 174 illustrate the decoding performance obtained using the base matrix BG1 after 5 iterations of the decoder.

It will be noted that the proposed structure according to at least one embodiment of the invention makes it possible to improve the performance of the LDPC decoder according to the 5G standard. The difference is especially great when the number of decoder iterations is lower.

### VARIANTS

An example has been described above in which the base matrix BG′ has a size identical to the base matrix BG1, with J=4, K=22 and M=46. This makes it possible in particular to be able to use the base matrix BG′ in any communications system according to the 5G standard.

However, this is a simple example, and other values for J, K and M may be envisaged, in particular for other transmission standards (Wi-Fi®, 6G, etc.).

A base matrix BG′ with five rotation factors V0 to V4 has likewise been proposed. However, a different number of rotation factors may be chosen.

Examples with a matrix B of the form

$$[ \begin{matrix}1 & 1 & 0 & 0 \\ 0 & 1 & 1 & 0 \\ 1 & 0 & 1 & 1 \\ 1 & 0 & 0 & 1\end{matrix} ]$$

have also been given. Other forms of the matrix B with at least one double diagonal may be used. In this case, the position of the connections and/or the values of the rotation factors may be updated so as to take into account the structure of the matrix B.

An LDPC code has also been taken as an example. The invention may also be extended to other error correcting codes using a parity matrix.

### Coding Device

Finally, with reference to FIG. 18, the simplified structure of an encoder according to at least one embodiment described above is presented.

As illustrated in FIG. 18, an encoder comprises at least one memory 181, at least one processing unit 182, equipped for example with a programmable computing machine or with a dedicated computing machine, for example a processor P, and driven by the computer program 183, implementing steps of the coding method according to at least one embodiment of the invention.

On initialization, the code instructions of the computer program 183 are for example loaded into a RAM memory, before being executed by the processor of the processing unit 182.

The processor of the processing unit 182 implements steps of the coding method described above, according to the instructions of the computer program 183, so as to code the K.Z source data using a parity matrix H of size (M.Z×N.Z), and deliver at least one codeword of size N.Z formed from the K.Z source data and from M.Z redundancy data.

1. A method for coding at least one block of K.Z source data, delivering at least one codeword of size N.Z formed from the K.Z source data and from M.Z redundancy data, N=K+M, with Z an integer expansion factor, Z≥1,
the method implementing a coding of the K.Z source data using a parity matrix H of size (M.Z×N.Z),
wherein the parity matrix H is obtained from a base matrix BG′ of size M×N, by replacing each element of the base matrix BG′ with an expansion matrix of size Z×Z,
the base matrix BG′ being expressed in the form:
$${BG}^{′} = [ \begin{matrix}A & B & 0 \\ C & D & I\end{matrix} ]$$
with:
A a kernel matrix of size J×K
B a matrix having at least one double diagonal of size J×J
C an extension matrix of size (M−J)×K
D a prolongation matrix of size (M−J)×J
0 a null matrix of size (N−K−J)×J
I an identity matrix of size (M−J)×(N−K−J)
and wherein the extension matrix C comprises at least two consecutive blocks of rows, each comprising a different number of rows, equal to a prime number or to the square of a prime number, each block of rows comprising at least one occurrence of a diagonal matrix.

2. The method for coding as claimed in claim 1, wherein at least one of the blocks of rows comprises at least two occurrences of the diagonal matrix.

3. The method as claimed in claim 1, wherein at least one of the blocks of rows comprises a number of rows greater than or equal to 4.

4. The method as claimed in claim 1, wherein for at least one of the blocks of rows, the extension matrix C comprises a portion of the diagonal matrix, and in that the prolongation matrix D comprises the prolongation of the portion.

5. The method as claimed in claim 1, wherein the number of non-null elements per column and/or per row with respect to the total number of elements per column and/or per row in the kernel matrix A, excluding the first two columns, is between 50 and 100%.

6. The method as claimed in claim 1, wherein the number of non-null elements per column and/or per row with respect to the total number of elements per column and/or per row in the kernel matrix A, excluding the first two columns, is between 75 and 100%.

7. The method as claimed in claim 1, wherein the first two columns of the kernel matrix A and/or of the extension matrix C comprise an alternation of non-null elements and null elements in each row and each column.

8. The method as claimed in claim 1, wherein J=4, K=22 and M=46.

9. The method as claimed in claim 1, wherein the kernel matrix A is equal to:

| | | | | | | | | | | | | | | | | | | | | | |
|---|---|---|---|---|---|---|---|---|---|---|---|---|---|---|---|---|---|---|---|---|---|
| V0 | | V0 | V1 | V3 | V4 | V3 | V2 | | V1 | V1 | V1 | | V1 | V4 | V0 | V4 | V2 | | V2 | V3 | V2 |
| | V2 | V2 | V2 | V3 | | V0 | | V0 | | V3 | V4 | V3 | V0 | | V1 | V2 | V1 | V0 | V3 | V4 | V0 |
| V1 | | V4 | V0 | V4 | | V0 | V2 | | V2 | | | V0 | | V0 | | V3 | V4 | V3 | | | V1 |
| | V0 | V4 | V1 | V2 | V1 | | V3 | V4 | V0 | V4 | | | V2 | V2 | V2 | | | V0 | V0 | V0 | |

the matrix B having at least one double diagonal is equal to:

| | | | |
|---|---|---|---|
| V1 | V0 | | |
| V0 | V0 | V0 | |
| | | V0 | V0 |
| V1 | | | V0 |

the extension matrix C is equal to:

| | | | | | | | | | | | | | | | | | | | | | |
|---|---|---|---|---|---|---|---|---|---|---|---|---|---|---|---|---|---|---|---|---|---|
| V0 | | V3 | | | | V0 | | | | V1 | | | | V2 | | | | V3 | | | |
| V3 | | | V1 | | | | V2 | | | | V3 | | | | V4 | | | | V1 | | |
| V1 | | | | V3 | | | | V4 | | | | V1 | | | | V0 | | | | V3 | |
| V3 | | | | | V1 | | | | V2 | | | | V3 | | | | V2 | | | | V1 |
| | V0 | V2 | | | | | V3 | | | | | V4 | | | | | V1 | | | | |
| V4 | | | V4 | | | | | V1 | | | | | V0 | | | | | V3 | | | |
| | V1 | | | V0 | | | | | V3 | | | | | V2 | | | | | V1 | | |
| | V3 | | | | V2 | | | | | V1 | | | | | V4 | | | | | V3 | |
| V0 | | | | | | V4 | | | | | V3 | | | | | V0 | | | | | V1 |
| | V4 | V1 | | | | | | | V0 | | | | | | | V3 | | | | | |
| V4 | | | V3 | | | | | | | V2 | | | | | | | V1 | | | | |
| | V4 | | | V1 | | | | | | | V4 | | | | | | | V3 | | | |
| | V0 | | | | V3 | | | | | | | V0 | | | | | | | V1 | | |
| | V2 | | | | | V1 | | | | | | | V2 | | | | | | | V3 | |
| V1 | | | | | | | V3 | | | | | | | V4 | | | | | | | V1 |
| | V1 | | | | | | | V1 | | | | | | | V0 | | | | | | |
| V1 | | V3 | | | | | | | | | V2 | | | | | | | | | V1 | |
| | V3 | | V1 | | | | | | | | | V4 | | | | | | | | | V3 |
| | V1 | | | V3 | | | | | | | | | V0 | | | | | | | | |
| V1 | | | | | V1 | | | | | | | | | V2 | | | | | | | |
| | V0 | | | | | V3 | | | | | | | | | V4 | | | | | | |
| | V4 | | | | | | V1 | | | | | | | | | V0 | | | | | |
| | V4 | | | | | | | V3 | | | | | | | | | V2 | | | | |
| V0 | | | | | | | | | V1 | | | | | | | | | V4 | | | |
| | V3 | | | | | | | | | V3 | | | | | | | | | V0 | | |
| V3 | | V1 | | | | | | | | | | | V4 | | | | | | | | |
| | V2 | | V3 | | | | | | | | | | | V0 | | | | | | | |
| V1 | | | | V1 | | | | | | | | | | | V2 | | | | | | |
| | V2 | | | | V3 | | | | | | | | | | | V4 | | | | | |
| V2 | | | | | | V1 | | | | | | | | | | | V0 | | | | |
| V3 | | | | | | | V3 | | | | | | | | | | | V2 | | | |
| V0 | | | | | | | | V1 | | | | | | | | | | | V4 | | |
| | V3 | | | | | | | | V3 | | | | | | | | | | | V0 | |
| V4 | | | | | | | | | | V1 | | | | | | | | | | | V2 |
| V2 | | | | | | | | | | | V3 | | | | | | | | | | |
| V2 | | | | | | | | | | | | V1 | | | | | | | | | |
| | V1 | V0 | | | | | | | | | | | | | V3 | | | | | | |
| V3 | | | V2 | | | | | | | | | | | | | V1 | | | | | |
| | V1 | | | V4 | | | | | | | | | | | | | V3 | | | | |
| | V4 | | | | VC | | | | | | | | | | | | | V1 | | | |
| | V4 | | | | | V2 | | | | | | | | | | | | | V3 | | |
| V2 | | | | | | | V4 | | | | | | | | | | | | | V1 | |

the prolongation matrix D is equal to:

| | | | |
|---|---|---|---|
| V4 | V0 | V2 | V2 |
| | V0 | | |
| | | V2 | |
| | | | V4 |
| V1 | | | |
| | V3 | | |
| | | V1 | |
| | | | V3 |
| | V2 | | |
| | | V4 | |
| | | | V0 |
| V3 | | | |
| V1 | | | |
| | V3 | | |
| | | V1 | |
| | | | V3 |
| | | V1 | |
| | | | V3 |
| V4 | | | |
| | V0 | | |

and wherein:
each empty or null element of the base matrix BG′ is replaced with a null matrix of size Z×Z,
each non-null element of the base matrix BG′ is replaced with a circular permutation matrix obtained by applying a circular rotation Vi to an identity matrix of size Z×Z, such that:

| | Circular rotation Vi |
|---|---|
| if Z belongs to | V0 = 0 + 4y, y ∈ [0:63] |
| {2, 4, 8, 16, 32, 128, 256}: | V1 = 1 + 4y, y ∈ [0:63] |
| | V2 = 2 + 4y, y ∈ [0:63] |
| | V3 = 3 + 4y, y ∈ [0:63] |
| | V4 = 0 + 4y, y ∈ [0:63] |
| if Z belongs to | V0 = 0 + 5x + 6y, x ∈ [0:1] and y ∈ [0:63] |
| {3, 6, 12, 24, 48, 96, 192, 384}: | V1 = 1 + 6y, y ∈ [0:63] |
| | V2 = 2 + 6y, y ∈ [0:63] |
| | V3 = 3 + 6y, y ∈ [0:63] |
| | V4 = 4 + 6y, y ∈ [0:63] |
| if Z belongs to | V0 = 0 + 5y, y ∈ [0:63] |
| {5, 10, 20, 40, 80, 160, 320}: | V1 = 1 + 5y, y ∈ [0:63] |
| | V2 = 2 + 5y, y ∈ [0:63] |
| | V3 = 3 + 5y, y ∈ [0:63] |
| | V4 = 4 + 5y, y ∈ [0:63] |
| if Z belongs to | V0 = 0 + 5x + 7y, x ∈ [0:1] and y ∈ [0:31] |
| {7, 14, 28, 56, 112.224}: | V1 = 1 + 5x + 7y, x ∈ [0:1] and y ∈ [0:31] |
| | V2 = 2 + 7y, y ∈ [0:31] |
| | V3 = 3 + 7y, y ∈ [0:31] |
| | V4 = 4 + 7y, y ∈ [0:31] |
| if Z belongs to | V0 = 0 + 5x + 9y, x ∈ [0:1] and y ∈ [0:31] |
| {9, 18, 36, 72, 144.288}: | V1 = 1 + 5x + 9y, x ∈ [0:1]and y ∈ [0:31] |
| | V2 = 2 + 5x + 9y, x ∈ [0:1] and y ∈ [0:31] |
| | V3 = 3 + 5x + 9y, x ∈ [0:1] and y ∈ [0:31] |
| | V4 = 4 + 9y, y ∈ [0:31] |
| if Z belongs to | V1 = 0 + 5x + 11y, x ∈ [0:2] and y ∈ [0:31] |
| {11, 22, 44, 88, 176.352}: | V1 = 1 + 5x + 11y, x ∈ [0:1] and y ∈ [0:31] |
| | V2 = 2 + 5x + 11y, x ∈ [0:1] and y ∈ [0:31] |
| | V3 = 3 + 5x + 11y, x ∈ [0:1] and y ∈ [0:31] |
| | V4 = 4 + 5x + 11y, x ∈ [0:1] and y ∈ [0:31] |
| if Z belongs to | V1 = 0 + 5x + 13y, x ∈ [0:2] and y ∈ [0:15] |
| {13, 26, 52, 104, 208}: | V1 = 1 + 5x + 13y, x ∈ [0:2] and y ∈ [0:15] |
| | V2 = 2 + 5x + 13y, x ∈ [0:2] and y ∈ [0:15] |
| | V3 = 3 + 5x + 13y, x ∈ [0:1] and y ∈ [0:15] |
| | V4 = 4 + 5x + 13y, x ∈ [0:1] and y ∈ [0:15] |
| | V1 = 0 + 5x + 15y, x ∈ [0:2] and y ∈ [0:15] |
| if Z belongs to | V1 = 1 + 5x + 15y, x ∈ [0:2] and y ∈ [0:15] |
| {15, 30, 60, 120, 240}: | V2 = 2 + 5x + 15y, x ∈ [0:2] and y ∈ [0:15] |
| | V3 = 3 + 5x + 15y, x ∈ [0:2] and y ∈ [0:15] |
| | V4 = 4 + 5x + 15y, x ∈ [0:2] and y ∈ [0:15] |

with x and y random variables.

10. A device for coding at least one block of K.Z source data, delivering at least one codeword of size N.Z formed from the K.Z source data and from M.Z redundancy data, N=K+M, with Z an integer expansion factor, Z≥1,
comprising at least one processing unit configured to code the K.Z source data using a parity matrix H of size (M.Z×N.Z),
the parity matrix H being obtained (52) from a base matrix BG′ of size M×N, by replacing each element of the base matrix BG′ with an expansion matrix of size Z×Z,
the base matrix BG′ being expressed in the form:
$${BG}^{′} = [ \begin{matrix}A & B & 0 \\ C & D & I\end{matrix} ]$$
with:
A a kernel matrix of size J×K
B a matrix having at least one double diagonal of size J×J
C an extension matrix of size (M−J)×K
D a prolongation matrix of size (M−J)×J
0 a null matrix of size (N−K−J)×J
I an identity matrix of size (M−J)×(N−K−J)
the extension matrix C comprising at least two consecutive blocks of rows, each comprising a different number of rows, equal to a prime number or to the square of a prime number, each block of rows comprising at least one occurrence of a diagonal matrix.

11. A processing circuit comprising a processor and a memory, the memory storing program code instructions of a computer program to execute the method of claim 1 when this computer program is executed by the processor.
